(19) United States
(12) Patent Application Publication
(10) Pub. No.: US 2013/0321088 A1
(43) Pub. Date: Dec. 5, 2013

(54) SURFACE MOUNT OVENIZED OSCILLATOR ASSEMBLY

(71) Applicants: Pierino Vidoni, Bienne (CH); Marc Yvain Pasche, Le Landeron (NE); Pierre Krummenacher, Evilard (BE)

(72) Inventors: Pierino Vidoni, Bienne (CH); Marc Yvain Pasche, Le Landeron (NE); Pierre Krummenacher, Evilard (BE)

(21) Appl. No.: 13/804,564

(22) Filed: Mar. 14, 2013

Related U.S. Application Data
(60) Provisional application No. 61/654,144, filed on Jun. 1, 2012.

(51) Int. Cl. H03L 1/04

(52) U.S. Cl. CPC H03L 1/04
USPC 331/70

(57) ABSTRACT

An oscillator assembly including a base substrate with a cavity defining an insulative air pocket. A component substrate is seated on the base substrate. An oscillator and a combination heater/temperature control assembly are located on one side and a temperature control assembly is located on the opposite side and extends into the cavity. An interior lid covers and defines an oven for the oscillator and the heater/temperature control assembly. An exterior lid covers the interior lid. A thermal resistance/heat transfer element is seated on the oscillator for increasing thermal resistance and is seated on both the oscillator and the heater/temperature control assembly for decreasing thermal resistance.

### CROSS-REFERENCE TO RELATED APPLICATIONS

This application claims the benefit of the filing date and disclosure of U.S. Provisional Application Ser. No. 61/654,144, filed on Jun. 1, 2012 which is explicitly incorporated herein by reference as are all references cited therein.

### FIELD OF THE INVENTION

The invention relates generally to oscillators and, more specifically to a surface mount ovenized oscillator assembly.

### BACKGROUND OF THE INVENTION

An oscillator circuit provides a stable-frequency output signal (typically sinusoidal) and, as those skilled in the electronics art will recognize, is an essential component for a variety of electronic devices that include communications equipment, navigation systems, and data processing equipment. Many oscillators employ a piezoelectric quartz crystal as a mechanism for generating and maintaining a stable output signal.

Quartz crystal resonant frequencies are temperature dependent. Stated alternatively, the output frequency of quartz crystals experience frequency shifts that are caused by temperature changes in the quartz element. When used in an oscillator circuit, the quartz crystal can cause the oscillator output frequency to shift as the quartz crystal's temperature changes.

Ovenized oscillators heat the temperature sensitive portions of the oscillator which is isolated from the ambient to a uniform temperature to obtain a more stable output frequency. Ovenized oscillators contain a heater, a temperature sensor, and circuitry to control the heater. The temperature control circuitry holds the crystal and critical circuitry at a precise, constant temperature. The best controllers are proportional, providing a steady heating current which changes with the ambient temperature to hold the oven at a precise set-point, usually about 10 degrees above the highest expected ambient temperature.

The output signal of a quartz crystal oscillator can also be kept steady over temperature by using circuits that sense temperature and which generate an appropriate corrective signal, which keeps the oscillator output frequency stable. Such a circuit is known as a temperature compensated crystal oscillator or “TCXO”. A TCXO is a quartz oscillator that employs active circuitry to generate a compensation signal that is used to keep the output of the oscillator device stable over wide-ranging temperatures. A TCXO can provide a very stable output signal over wide temperature swings and is a preferred oscillator in many communications applications and is the oscillator of choice where highly stable frequency sources are required.

The present invention is directed to a lower cost, easier to manufacture surface mount oscillator assembly incorporating the high performance of an ovenized oscillator with the low cost of a temperature controlled crystal oscillator.

### SUMMARY OF THE INVENTION

The present invention is generally directed to an oscillator assembly comprised of a base surface mount substrate which includes a top surface and defines a cavity; a component surface mount substrate which includes an oscillator and a heater mounted on a top surface and a temperature control assembly mounted on a bottom surface, the component surface mount substrate being direct surface mounted to the top surface of the base surface mount substrate in a relationship wherein the temperature control assembly is located inside the cavity defined in the base surface mount substrate; an interior lid which is seated on the top surface of the component surface mount substrate and covers both the oscillator and the heater and defines an oven; and an exterior lid which is coupled to the base surface mount substrate and covers the interior lid and the top surface of the base and component surface mount substrates.

In one embodiment, the oscillator is a temperature compensated crystal oscillator.

In one embodiment, the oscillator is a voltage controlled temperature compensated crystal oscillator.

In one embodiment, the base surface mount substrate includes first and second pluralities of surface mount connection pads defined on the top and bottom surfaces thereof respectively and the component surface mount substrate includes a first plurality of surface mount connection pads on the bottom surface thereof for direct surface coupling of the base surface mount substrate to a motherboard and the component surface mount substrate to the base surface mount substrate.

In one embodiment, the heater and a temperature sensor are located in the same case.

In one embodiment, the heater is a transistor and the temperature sensor is a diode.

In one embodiment, the oscillator assembly further comprises a heat transfer element seated on the oscillator for increasing the thermal resistance of the oscillator.

In one embodiment, the oscillator assembly further comprises a heat transfer element seated on both the oscillator and the heater for decreasing the thermal resistance of the oscillator.

The present invention is also directed to an oscillator assembly that comprises an oscillator and a combination heater and temperature sensor assembly located on a first side of a component substrate and a temperature control assembly located on a second opposed side of the component substrate, the combination heater and temperature sensor assembly including a heater and a temperature sensor located together in the same enclosure.

In one embodiment, the oscillator assembly further comprises a base substrate which includes a top surface and defining a cavity, the component substrate being seated on the top surface of the base substrate in a relationship wherein the temperature control assembly is located inside the cavity.

In one embodiment, the oscillator assembly further comprises a first lid covering the oscillator and the combination heater and temperature sensor assembly and a second lid that covers the first lid.

In one embodiment, the oscillator assembly further comprises a heat transfer element seated on the oscillator.

In one embodiment, the heat transfer element is also seated on the combination heater and temperature sensor assembly.

The present invention is further directed to an oscillator assembly that comprises an oscillator on the first surface of a component substrate; a heater on the first surface of the component substrate; and a thermal resistance element seated on the oscillator for adjusting the thermal resistance between the oscillator and the heater.

In one embodiment of the oscillator assembly, the thermal resistance element is seated on the oscillator and the heater for decreasing the thermal resistance between the oscillator and the heater.

In one embodiment, the oscillator assembly further comprises a base substrate which includes a first surface and defines a cavity; a temperature control assembly on a second surface of the component substrate, the component substrate being seated on the first surface of the base substrate and the temperature control assembly being located in the cavity; and a first lid which covers the oscillator and the heater.

In one embodiment, the oscillator assembly further comprises a second lid covering the first lid.

Other advantages and features of the present invention will be more readily apparent from the following detailed description of the preferred embodiment of the invention, the accompanying drawings, and the appended claims.

### BRIEF DESCRIPTION OF THE DRAWINGS

These and other features of the invention can best be understood by the following description of the accompanying FIGURES as follows:

FIG. 1 is a perspective view of a surface mount oscillator assembly in accordance with the present invention;

FIG. 2A is a simplified vertical cross-sectional view of the surface mount oscillator assembly shown in FIG. 1 with a thermal resistance/heat transfer element seated on the oscillator;

FIG. 2B is a simplified vertical cross-sectional view of the surface mount oscillator assembly shown in FIG. 1 with a thermal resistance/heat transfer element seated on both the oscillator and the heater/temperature sensor assembly;

FIG. 3 is a circuit block diagram of the surface mount oscillator assembly shown in FIGS. 1, 2A, and 2B;

FIG. 4 is a circuit block diagram of an alternate embodiment of the heater/temperature sensor assembly of the surface mount oscillator assembly shown in FIGS. 1, 2A, and 2B;

FIG. 5 is a circuit block diagram of another alternate embodiment of the heater/temperature sensor assembly of the surface mount oscillator assembly shown in FIGS. 1, 2A, and 2B;

FIG. 6 is a simplified perspective view of the base substrate of the surface mount oscillator assembly shown in FIGS. 1, 2A, and 2B without the thermal resistance/heat transfer element;

FIG. 7 is a simplified perspective top view of the component substrate of the surface mount oscillator assembly shown in FIGS. 1, 2A, and 2B;

FIG. 8 is a simplified perspective view of the lower surface of the component substrate of the surface mount oscillator assembly shown in FIGS. 1, 2A, and 2B; and

FIG. 9 is a simplified perspective view of the surface mount oscillator assembly of FIGS. 1, 2A, and 2B with the exterior lid/cover removed therefrom.

### DETAILED DESCRIPTION OF THE EMBODIMENTS

FIGS. 1-9 depict a surface mount oscillator assembly 10 in accordance with the present invention which, in the embodiment shown, is in the form of an oversized temperature compensated crystal oscillator (TCXO) assembly.

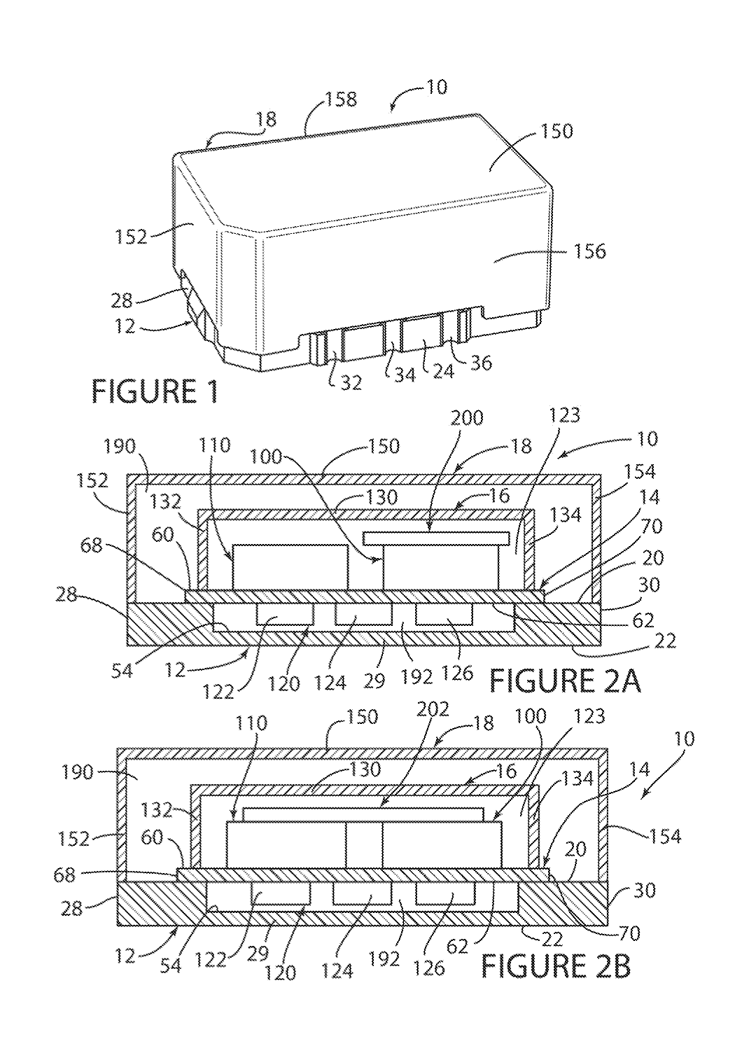

As shown in FIGS. 1, 2A, and 2B, the oscillator assembly 10 comprises the following main components: a base surface mount substrate 12; a component substrate 14 (FIGS. 2A and 2B) located and seated and mounted on and against the top surface of the base substrate 12; a first internal lid/cover 16 (FIGS. 2A and 2B) located and seated and mounted on and against the top surface of the component substrate 14 and covering the elements located and seated and mounted on the top surface of the component substrate 14; and a second external lid/cover 18 located and seated and mounted on and surrounding the base substrate 12 and covering the top surface of the base substrate 12, the component substrate 14, and the interior lid/cover 16.

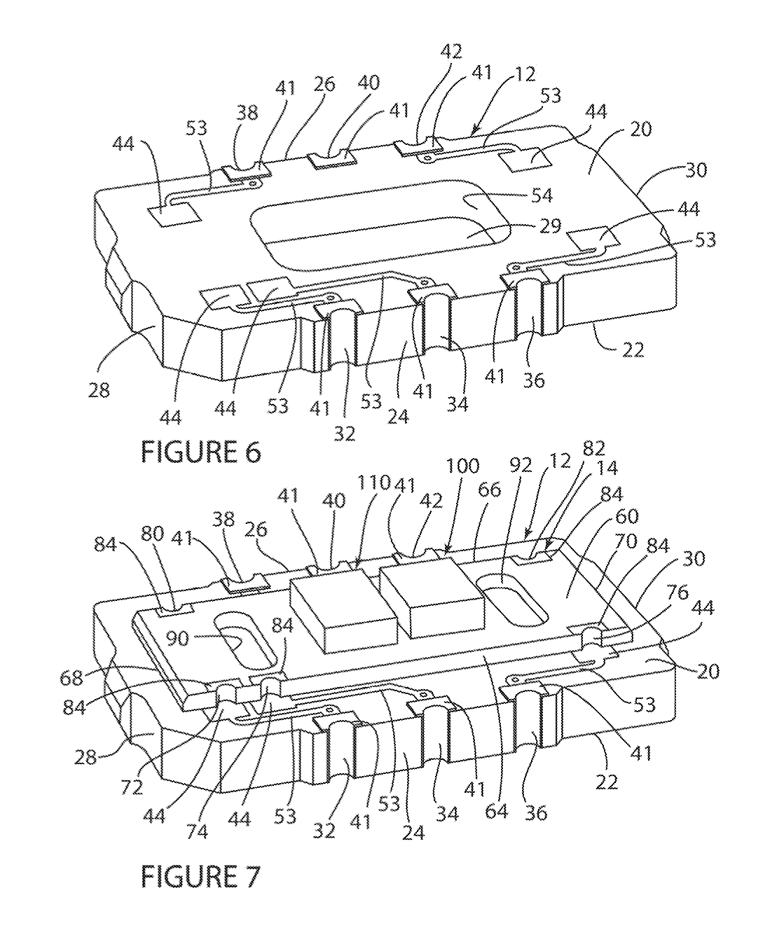

As more particularly shown in FIGS. 2A, 2B, and 6, the base surface mount substrate 12 is, in the embodiment shown, in the form of a generally rectangularly-shaped printed circuit board (PCB) made of any suitable material such as, for example, FR4 material and which includes a first or top surface 20, a second or bottom surface 22 (FIGS. 2A and 2B), a pair of opposed and longitudinally extending vertical side surfaces/faces 24 and 26 (FIG. 6), and a pair of opposed and transversely extending vertical side surfaces/faces 28 and 30.

The longitudinally extending vertical side surface/face 24 of the substrate 12 includes three spaced-apart, parallel, and vertically oriented castellations or recesses 32, 34, and 36 (FIG. 6) which are covered with conductive material and extend between, and normal to, the top and bottom surfaces 20 and 22 respectively of the substrate 12.

The opposed longitudinally extending vertical side surface/face 26 of the substrate 12 also includes three spaced-apart, parallel, and vertically oriented conductive castellations or recesses 38, 40, and 42 (FIG. 6) which are also covered with conductive material and also extend between, and normal to, the top and bottom surfaces 20 and 22 of the substrate 12 in a relationship diametrically opposed to the respective castellations 32, 34, and 36 on the opposed longitudinally extending vertical side surface/face 24 of the substrate 12.

A region or pad or ring 41 of conductive material is formed on the top surface 20 of the base substrate 12, surrounds each of the openings defined by each of respective castellations 32, 34, 36, 38, 40, and 42 in the top surface 20 of the base substrate 12, and is in contact with the conductive material covering each of the respective castellations 32, 34, 36, 38, 40, and 42.

Although not shown in any of the FIGURES, it is understood that a mounting/solder region or pad or ring of conductive material similar to the region or pad 41 is formed on the bottom surface 22 of the base substrate 12, surrounds each of the openings defined by each of the respective castellations 32, 34, 36, 38, 40, and 42 in the bottom surface 22 of the base substrate 12, and is in contact with the conductive material covering each of the respective castellations 32, 34, 36, 38, 40, and 42.

A plurality of additional mounting/solder regions or pads 44 of conductive material are formed on the top surface 20 of the base substrate 12 and are electrically connected to respective ones of the pads 41 of the respective castellations 32, 34, 36, 38, and 42 via respective strips 53 of conductive material also formed on the top surface 20 of the base substrate 12 and extending between respective ones of the pads or rings 41 and respective ones of the pads 44.

The base substrate 12 additionally includes and defines a centrally located and generally rectangularly-shaped cavity or recess 54 (FIGS. 2A, 2B, and 6) extending inwardly into the body of the substrate 12 from the top surface 20 thereof.

In accordance with this embodiment, and although not shown in any of the FIGURES, the base substrate 12 is adapted for direct surface mounting onto the top surface of a motherboard in a relationship wherein the mounting/solder pads (not shown) on the bottom surface 22 of the base substrate 12 are abutted and coupled to respective mounting/solder pads (not shown) on the surface of the motherboard (not shown).

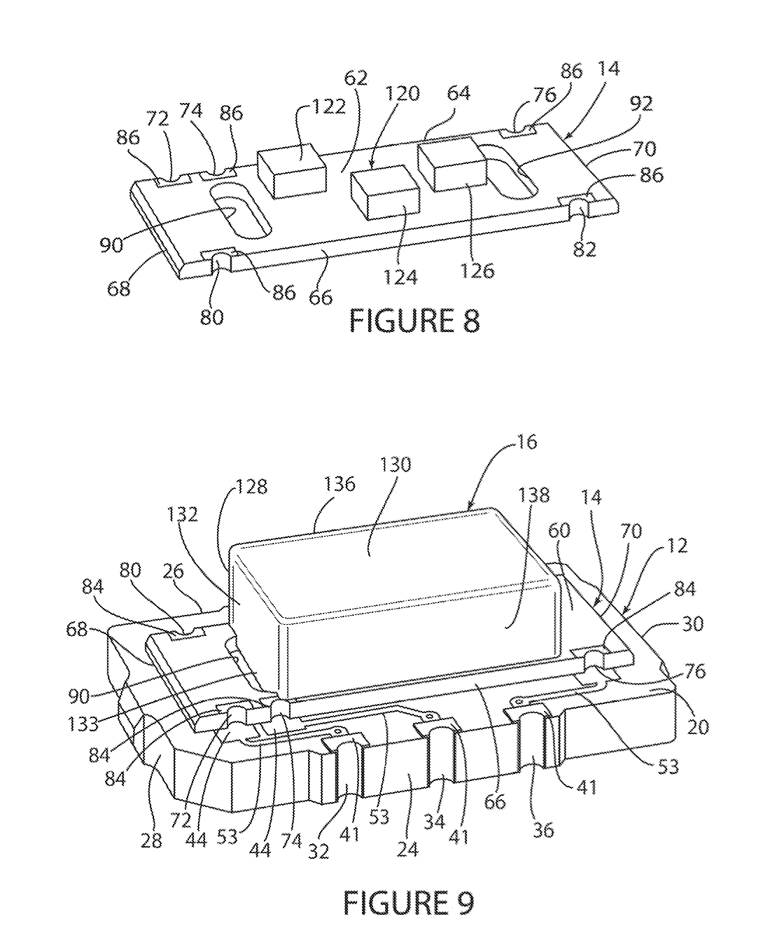

As shown in FIGS. 7 and 8, the oscillator assembly 10 further comprises the component substrate 14 which, in the embodiment shown, is also in the form of a generally rectangularly-shaped printed circuit board (PCB) made of any suitable material such as, for example, FR4 material and which includes a first or top surface 60 (FIG. 7), a second or bottom surface 62 (FIG. 8), a pair of opposed and longitudinally extending vertical side surfaces/faces 64 and 66, and a pair of opposed and transversely extending vertical side surfaces/faces 68 and 70.

The longitudinally extending vertical side surface/face 64 of the substrate 14 includes three spaced-apart, parallel, and vertically oriented castellations or recesses 72, 74, and 76 which are covered with a layer of conductive material and extend between, and normal to, the top and bottom surfaces 60 and 62 respectively of the substrate 14. In the embodiment shown, the two castellations 72 and 74 are located adjacent the transverse side surface/face 68 of the substrate 14 and the transverse castellation 76 is located adjacent the side surface/face 70 of the substrate 14.

The opposed longitudinally extending vertical side surface/face 66 of the substrate 14 includes two spaced-apart, parallel, and vertically oriented castellations or recesses 80 and 82 which are covered with a layer of conductive material and extend between, and in an orientation generally normal to the top and bottom surfaces 60 and 62 respectively of the substrate 14. In the embodiment shown, the castellation 80 is located adjacent the transverse side surface/face 68 of the substrate 14 in a relationship diametrically opposed to the castellation 72 defined in the longitudinally extending vertical side surface/face 66 and the castellation 82 is located adjacent the opposed transverse side surface/face 70 in a relationship diametrically opposed to the castellation 76 defined in the longitudinally extending side surface/face 66 of the substrate 14.

A region or pad or ring 84 of conductive material is formed on the top surface 60 of the substrate 14, surrounds each of the respective openings defined by each of the castellations 72, 74, 76, 80, and 82 in the top surface 60 of the substrate 14, and is in contact with the conductive material covering the surface of each of the castellations 72, 74, 76, 80, and 82.

Similarly, a mounting/solder region or pad 86 of conductive material is formed on the bottom surface 62 of the substrate 14, surrounds each of the respective openings defined by each of the castellations 72, 74, 76, 80, and 82 in the bottom surface 62 of the substrate 14, and is in contact with the conductive material covering the surface of each of the castellations 72, 74, 76, 80, and 82.

The substrate 14 additionally defines and includes a pair of spaced-apart, parallel, and generally oval-shaped slits 90 and 92 that extend through the substrate 14 in a relationship and orientation generally normal to the opposed longitudinally extending side surfaces/faces 64 and 66 of the substrate 14.

The slit 90 is located in the substrate 14 adjacent and parallel to the transverse side surface/face 68 of the substrate 14 and in a relationship generally co-linear with the castellation 82 defined in the longitudinally extending side surface/face 64 of the substrate 14, The slit 92 is located in the substrate 14 adjacent and parallel to the opposed transverse side surface/face 70 of the substrate 14.

In the embodiment shown, the castellations 72 and 80 are located on the substrate 14 between the transverse side surface/face 68 and the slit 90 on the substrate 14; the castellation 74 is positioned generally co-linearly with the slit 90; and the castellations 76 and 82 are located on the substrate 14 between the slit 92 and the transverse side surface/face 70 of the substrate 14.

An oscillator 100 (FIGS. 2A, 2B, and 7) which, in the embodiment shown, is in the form of a temperature compensated crystal oscillator (TCXO) which may be a voltage controlled temperature compensated crystal oscillator (VCTCXO), is located and seated and mounted on and against the top side or surface 60 of the substrate 14 in the region of the top surface 60 between the two slits 90 and 92.

A combination oven heater and temperature sensor assembly 110 (FIGS. 2A, 2B, and 7) is also located and seated and mounted on and against the top surface or side 60 of the substrate 14 and is located thereon between the slit 90 and the oscillator 100. In the embodiment shown, the oscillator 100 and the heater/temperature sensor assembly 110 are seated on the surface 60 of the substrate 14 in an adjacent, side-by-side, and parallel relationship.

In the embodiment shown, and with reference to FIGS. 2A, 2B, 3, and 7, the combination oven heater/temperature sensor assembly 110 includes a heater 111 in the form of a transistor and a temperature sensor 113 in the form of a diode which can either be located and mounted together in the same case or enclosure as the heater 111 as shown in FIGS. 2A and 2B or on the same chip as the heater 111 for providing a tight coupling, less thermal resistance, and a lower thermal time constant.

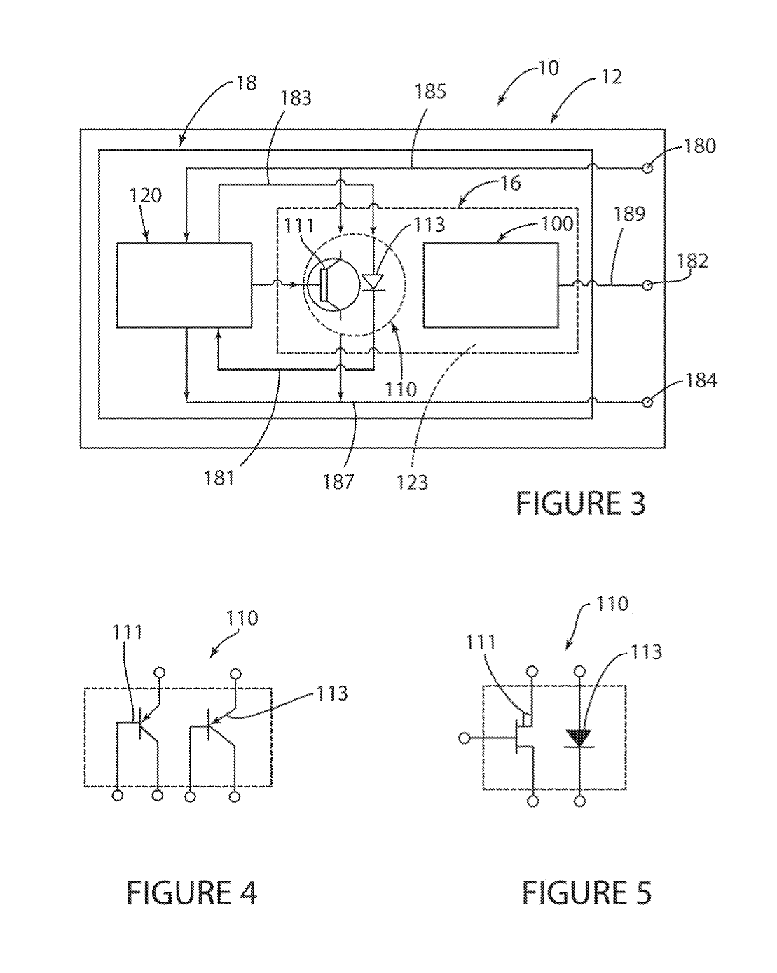

FIGS. 3-5 depict different embodiments of the transistor heater 111 which can be bipolar (PNP or NPN) or MOS (P or N channel) transistor and different embodiments of the temperature sensor diode which can be in the form of a Schottky diode (FIG. 3), a normal diode (FIG. 4), or a bipolar diode (FIG. 5) where the base-emitter diode is used.

The substrate 14 also includes an oscillator temperature control assembly 120 (FIGS. 2A, 2B, and 8) including a plurality of temperature control elements 122, 124, and 126 located and seated and mounted on and against the bottom surface 62 of the substrate 14 in the region of the bottom surface 62 of the substrate 14 located between the two slits 90 and 92. Although not shown or disclosed herein in any detail, it is understood that the temperature control assembly 120 includes such elements as a temperature controller, a regulator, a power resistor, and other components suitable for providing the requisite oscillator temperature control.

Thus, in the embodiment shown, the oscillator 100 and heater and temperature sensor assembly 100 on the one hand and the elements 122, 124, and 126 of the temperature control assembly 120 on the other hand are located, seated, and mounted on and to opposite sides of the substrate 14.

Although not shown or described herein in any detail, it is also understood that a plurality of additional strips of conductive material are formed on both the top and bottom surfaces 60 and 62 of the substrate 14 for connecting the various components on the top and bottom surfaces 60 and 62 of the component substrate 14 to each other and to respective ones of the castellations 72, 74, 76, 80, and 82 on the substrate 14 and for electrically interconnecting the oscillator and heater components on the top surface 60 of the substrate 14 to the temperature control components on the bottom surface 62 of the substrate 14.

As shown in FIGS. 2A, 2B, and 7, the substrate 14 is located and seated and mounted on and against the top surface 20 of the base substrate 12 in a relationship wherein the components/elements 122, 124, and 126 of the oscillator temperature control assembly 120 are located in the cavity 54 defined in the base substrate 12; and the respective pads 86 on the bottom surface 62 of the substrate 14 are abutted against and coupled to respective ones of the pads 44 on the top surface 20 of the base substrate 12 to provide an electrical connection between the base substrate 12 and the components/elements on the respective top and bottom surfaces 60 and 62 of the substrate 14.

As shown in FIGS. 2A, 2B, and 9, the oscillator assembly 10 still further comprises the first interior oven lid/cover 16 which is located and seated and mounted on and against the top surface 20 of the substrate 14.

The lid/cover 16 which, in the embodiment shown, is generally rectangularly- and box-shaped, is made of a suitable insulative material such as, for example, PEEK, and includes a flat horizontal roof 130 and four sides 132, 134, 136, and 138 which depend downwardly normally from the four respective peripheral edges of the roof 130 and terminate in four respective distal peripheral end faces abutted and mounted on and against the top surface 60 of the substrate 14. Each of the sides 132 and 134 additionally includes and defines a distal tab 133 (only one of which is shown in FIG. 9).

In the embodiment shown, the lid/cover 16 is seated on and against the portion of the substrate 14 bounded generally by and between the two transverse slits 90 and 92 and the two opposed longitudinally extending side surfaces/faces 64 and 66 of the substrate 14 in a relationship wherein the respective distal peripheral end faces of the lid/cover 16 are abutted and secured, as by gluing or the like, to the top surface 60 of the substrate 14 and the respective tabs 133 on the lid/cover 16 extend into the respective slits 90 and 92.

In the position of the lid/cover 16 as shown in FIGS. 2A, 2B, and 9, the lid/cover 16 covers both the oscillator 100 and the heater/temperature sensor assembly 110 and defines an interior oven enclosure 123 (FIGS. 2A and 2B) for both the oscillator 100 and the heater/temperature sensor assembly 110.

Referring to FIGS. 1, 2A, and 2B, the oscillator assembly 10 still further comprises the external lid/cover 18 which covers both of the substrates 12 and 14 and the interior lid/cover 16 and is seated on the top surface 20 of the substrate 12.

The external lid/cover 18 which, in the embodiment shown, is also generally rectangularly- and box-shaped, is also made of a suitable insulative material such as, for example, PEEK and includes a flat horizontal roof 150 and four sides 152, 154, 156, and 158 which depend and extend normally downwardly from the four respective peripheral edges of the roof 150 and terminate in four respective distal peripheral end faces abutted against the top surface 20 of the substrate 12.

In the embodiment as shown in FIG. 1, the external lid/cover 18 is located and seated and mounted on and against the base substrate 12 in a relationship wherein the four respective distal peripheral edges of the four respective sides 152, 154, 156, and 158 of the lid/cover 18 surround and are abutted against the exterior face of the respective side surfaces 28, 30, 24, and 26 of the base substrate 12 and the lid/cover 18 covers and defines an interior enclosure for the interior oven lid/cover 16, the peripheral portion of the top surface 60 of the oscillator substrate 14 not covered by the lid/cover 16, and the peripheral portions of the top surface 20 of the base substrate 12 not covered by the oscillator substrate 14.

In accordance with the operation of the oscillator assembly 10 of the present invention, the dissipated power of the heater 111 of the heater/temperature sensor assembly 110 is proportionally controlled to heat and maintain a constant temperature inside the oven 123 (FIGS. 2A and 2B) defined by the interior lid/cover 16. The temperature sensor 113 of the heater/temperature sensor assembly 110 monitors the temperature of the oscillator 100 and the temperature control assembly 120 and, more specifically, the elements 122, 124, and 126 thereof, receive a differential temperature signal 181 and 183 (FIG. 3) as an input from the temperature sensor 113 and provides a heater control signal for the heater 111 (FIG. 3) as an output.

When the temperature is below the selected set point for the oven 123, the temperature control assembly 120 increases power supplied through the power terminal 180 and circuit line 185 in FIG. 3 to the heater 111 and the temperature sensor 113 to increase the temperature in the oven 123.

When the temperature is above the set point for the oven 123, the temperature control assembly 120 reduces power to the heater 111 to allow a decrease in the temperature in the oven 123.

As shown in FIG. 3, each of the heater/temperature sensor assembly 110 and temperature control assembly 120 is coupled to ground terminal 184 via circuit line 187. An oscillator frequency signal is outputted through frequency output terminal 182 via circuit line 189 that extends between the oscillator 100 and the terminal 182 as shown in FIG. 3.

Further, in accordance with the operation of the oscillator assembly 10 of the present invention, the external lid/cover 18 provides a second layer or zone or region 190 (FIGS. 2A and 2B) of insulation in the interior of the oscillator 10 between the two lids 16 and 18; the cavity 54 in the base substrate 12 defines an insulative air pocket 192 (FIGS. 2A and 28) between the floor or base or bottom 29 of the substrate 12 and the lower surface 62 of the substrate 14 for the temperature control assembly 120 and, more specifically, the components 122, 124, and 126 thereof; and the slits 90 and 92 defined in the component substrate 14 provide for better thermal insulation of the oven 123, less longitudinal temperature propagation through the body of the component substrate 14, and define receptacles or pockets for the tabs 133 on the lid/cover 16.

Still further, as a result of the placement and seating of both the oscillator 100 and the heater/temperature sensor assembly 110 in close proximity to each other on the same side of the substrate 14, it is understood that there is a thermal resistance between the oscillator 100 and the heater/temperature sensor assembly 110. This thermal resistance must be compensated to assure the proper operation and performance of the oscillator assembly 10.

Oscillators in use today include complex electronic temperature compensation circuits. The present invention, however, includes the use of thermal resistance/temperature compensation/heat transfer elements 200 (FIG. 2A) and 202 (FIG. 2B) which, in the embodiments shown, are in the form of elongate bars made of any suitable heat conducting/ heat transfer material including, for example, copper-beryllium (CuBe₂).

The thermal resistance element embodiment 200 as shown in FIG. 2A located and seated and mounted on and against the top surface of the oscillator 100 is suitable for use in an under-compensation or negative temperature compensation slope setting in which the temperature of the oscillator 100 is higher than desired.

In this setting, thermal resistance needs to be added or increased, and the element 200 acts as a heat sink by allowing for the transferring of excess heat from the oscillator 100 into the element 200, thereby reducing the temperature of the oscillator 100 to the desired temperature.

The size of the element 200 can be adjusted as desired to adjust the amount of heat transferred into the element 200, and thus adjust and control he amount by which the temperature of the oscillator 100 is reduced, and thus adjust and control the amount by which the thermal resistance of the oscillator 100, and thus the thermal resistance between the oscillator 100 and the heater/temperature sensor assembly 110, is increased.

The thermal resistance element embodiment 202 shown in FIG. 2A, in which a first distal end thereof is located and seated and mounted on and against the top surface of the oscillator 100 and in which an opposed second distal end thereof is located and seated and mounted on and against the top surface of the heater/temperature sensor assembly 110, is suitable for use in an over-compensation or positive temperature compensation slope setting in which the temperature of the oscillator 100 is lower than desired.

In this setting, the thermal resistance needs to be subtracted, i.e., thermal resistance between the oscillator 100 and the heater/temperature sensor assembly 100 needs to be reduced, and the element 202 acts as a heat conductive bridge that allows for heat generated by the heater/temperature sensor assembly 110 to be transferred from the heater/temperature sensor assembly 110 to the element 202 and then from the element 202 to the oscillator 100 for increasing the temperature of the oscillator 100 to the desired temperature.

The size of the element 202 can be adjusted as desired to adjust the amount of heat transferred into the element 202 from the heater/temperature sensor assembly 110 and then back into the oscillator 100, and thus adjust and control the amount by which the temperature of the oscillator 100 is increased, and thus adjust and control the amount by which the thermal resistance of the oscillator 100, and thus the thermal resistance between the oscillator 100 and the heater/temperature sensor assembly 110, is decreased.

While the invention has been taught with specific reference to the embodiments shown, it is understood that a person of ordinary skill in the art will recognize that changes can be made in form and detail without departing from the spirit and the scope of the invention. The described embodiments are to be considered in all respects only as illustrative and not restrictive.

We claim:

1. An oscillator assembly comprising:
a base surface mount substrate including a top surface and defining a cavity;
a component surface mount substrate including an oscillator and a heater mounted on a top surface and a temperature control assembly mounted on a bottom surface, the component surface mount substrate being direct surface mounted to the top surface of the base surface mount substrate in a relationship wherein the temperature control assembly is located inside the cavity defined in the base surface mount substrate;
an interior lid seated on the top surface of the component surface mount substrate and covering both the oscillator and the heater and defining an oven; and
an exterior lid coupled to the base surface mount substrate and covering the interior lid and the top surface of the base and component surface mount substrates.

2. The oscillator assembly of claim 1 wherein the oscillator is a temperature compensated crystal oscillator.

3. The oscillator assembly of claim 2 wherein the oscillator is a voltage controlled temperature compensated crystal oscillator.

4. The oscillator assembly of claim 1 wherein the base surface mount substrate includes first and second pluralities of surface mount connection pads defined on the top and bottom surfaces thereof respectively and the component surface mount substrate includes a first plurality of surface mount connection pads on the bottom surface thereof for direct surface coupling of the base surface mount substrate to a motherboard and the component surface mount substrate to the base surface mount substrate.

5. The oscillator assembly of claim 1 wherein the heater and a temperature sensor are located in the same case.

6. The oscillator assembly of claim 5 wherein the heater is a transistor and the temperature sensor is a diode.

7. The oscillator assembly of claim 1 further comprising a heat transfer element seated on the oscillator for increasing the thermal resistance of the oscillator.

8. The oscillator assembly of claim 1 further comprising a heat transfer element seated on both the oscillator and the heater for decreasing the thermal resistance of the oscillator.

9. An oscillator assembly comprising an oscillator and a combination heater and temperature sensor assembly located on a first side of a component substrate and a temperature control assembly located on a second opposed side of the component substrate, the combination heater and temperature sensor assembly including a heater and a temperature sensor located together in the same enclosure.

10. The oscillator assembly of claim 9 further comprising a base substrate including a top surface and defining a cavity, the component substrate being seated on the top surface of the base substrate in a relationship wherein the temperature control assembly is located inside the cavity.

11. The oscillator assembly of claim 10 further comprising a first lid covering the oscillator and the combination heater and temperature sensor assembly and a second lid that covers the first lid.

12. The oscillator assembly of claim 9 further comprising a heat transfer element seated on the oscillator.

13. The oscillator assembly of claim 12 wherein the heat transfer element is also seated on the combination heater and temperature sensor assembly.

14. An oscillator assembly comprising:
an oscillator on the first surface of a component substrate;
a heater on the first surface of the component substrate; and
a thermal resistance element seated on the oscillator for adjusting the thermal resistance between the oscillator and the heater.

15. The oscillator assembly of claim 14 wherein the thermal resistance element is seated on the oscillator and the heater for decreasing the thermal resistance between the oscillator and the heater.

16. The oscillator assembly of claim 14 further comprising:
a base substrate including a first surface and defining a cavity;
a temperature control assembly on a second surface of the component substrate, the component substrate being seated on the first surface of the base substrate and the temperature control assembly being located in the cavity; and
a first lid covering the oscillator and the heater.

17. The oscillator assembly of claim 16 further comp sing a second lid covering the first lid.
